(19) United States
(12) Patent Application Publication
(10) Pub. No.: US 2016/0141729 A1
(43) Pub. Date: May 19, 2016

(54) PROTECTION APPARATUS FOR RECHARGEABLE BATTERY AND PROTECTION METHOD FOR RECHARGEABLE BATTERY USING THE SAME

(71) Applicant: SAMSUNG SDI CO., LTD., Yongin-si (KR)

(72) Inventor: Duk-Jung KIM, Yongin-si (KR)

(21) Appl. No.: 14/935,954

(22) Filed: Nov. 9, 2015

(30) Foreign Application Priority Data
Nov. 13, 2014 (KR) 10-2014-0158162

(51) Int. Cl. H01M 10/42; H01M 2/34; H01M 10/48; G01R 31/36

(52) U.S. Cl. CPC H01M 10/425; G01R 31/362; G01R 31/3682; G01R 31/3658; H01M 2/345; H01M 10/48; H01M 2010/4271; H01M 2200/20

(57) ABSTRACT

A protection apparatus for a rechargeable battery includes a battery module, a cathode power line, an anode power line, a signal line, and a battery protector. The battery module includes a unit cell, a conductor case, a cathode, and an anode. The battery protector measures a charged voltage of the unit cell through the cathode power line and the anode power line, measures a detection voltage of the unit cell through the anode power line and the signal line, and determines a charged state of the unit cell based on a calculated voltage ratio of the charged voltage and the detection voltage.

### CROSS-REFERENCE TO RELATED APPLICATION

Korean Patent Application No. 10-2014-0158162, filed on Nov. 13, 2014, and entitled, “Protection Apparatus For Rechargeable Battery and Protection Method For Rechargeable Battery Using the Same,” is incorporated by reference herein in its entirety.

### BACKGROUND

1. Field

One or more embodiments described herein relate to a protection apparatus for a rechargeable battery and a method for protecting a rechargeable battery.

2. Description of the Related Art

A variety of rechargeable batteries have been developed. Examples include nickel-hydride batteries and lithium ion batteries. Rechargeable batteries are used for powering mobile devices, electric automobiles, hybrid automobiles, and other devices.

Rechargeable batteries have different capacities based on their intended use. Small-capacity rechargeable batteries are used, for example, in portable electronic devices such as mobile phones. notebook computers, and camcorders. Large-capacity rechargeable batteries are used. for example, to drive the motor of a hybrid automobile. Moreover, rechargeable batteries may be used singularly, in a modular state in which a plurality of unit cells are electrically connected to each other, or a pack state in which a plurality of modules are electrically connected to each other.

When a rechargeable battery is over-charged, the voltage of the rechargeable battery may increase, which, in turn, may result in the generation of gases with the battery case. As a result, the pressure in the case increases, and consequently the case may expand or even explode.

### SUMMARY

In accordance with one or more embodiments, a protection apparatus for a rechargeable battery including a battery module including a unit cell, a conductor case, a cathode, and an anode; a cathode power line connected to the cathode; an anode power line connected to the anode; a signal line connected to the case; and a battery protector to measure a charged voltage of the unit cell through the cathode power line and the anode power line, to measure a detection voltage of the unit cell through the anode power line and the signal line, and to determine a charged state of the unit cell based on a calculated voltage ratio of the charged voltage and the detection voltage.

The battery module may include a plate extending from the case and connected to the signal line; and a connection tab connected to the cathode and a connection point in contact with the plate, wherein the plate is to deform when an internal pressure of the battery module exceeds a preset reference value, and wherein contact between the connection point and the plate is broken when the plate deforms. The plate may contact point forming body having a shape to be permanently deformed when the internal pressure of the case exceeds the preset reference value. When the internal pressure of the case exceeds the preset reference value, the plate may be permanently deformed to be convex in an outer direction of the case.

When the voltage ratio is at a first predetermined value or more, the battery protector may determine the charged state of the unit cell to be a normal state, and when the voltage ratio is less than the first predetermined value, the battery protector may determine the charged state of the unit cell to be in an abnormal over-charged state. When the voltage ratio is equal to a second predetermined value, the battery protector may determine the charged state of the unit cell to be in an over-charged state.

In accordance with one or more other embodiments, a protector includes a first input coupled to an anode power line; a second input coupled to a cathode power line; a third input to receive a pressure signal for a case of the battery; and logic to generate a mode signal based on signals received through the first, second, and third inputs, wherein the mode signal is indicative of a warning mode indicating that pressure in the battery case at a level between a normal mode and an abnormal mode of the battery, and wherein the logic is to perform a monitoring operation to monitor charged voltages of one or more cells of a rechargeable battery based on the warning mode, the monitoring operation to be performed to determine a change from the warning mode to the abnormal mode. The first, second, and third inputs may be, for example, inputs of an integrated circuit or processing circuit.

The pressure in the battery case may be at a first level in warning mode, the pressure in the battery case may be at a second level in the abnormal mode, and the second level may be greater than the first level. The first level may correspond to a first overcharge state of the battery, the second level may correspond to a second overcharge state of the battery, and the second overcharge state may be more severe than the first overcharge state.

The logic may generate the mode signal indicative of the warning mode when the pressure signal has a first value, and the logic may generate the mode signal indicative of the normal mode when the pressure signal has a second value different from the first value. The first value may have a zero value and the second value may have a non-zero value.

The logic may generate the mode signal to be indicative of the warning mode when the pressure signal corresponds to a disconnection between first and second nodes connected to the battery, and the logic may generate the mode signal to be indicative of the normal mode when the pressure signal corresponds to a connection between the first and second nodes connected to the battery.

The pressure signal corresponding to the warning mode may be generated when a conductor moves from a first position to a second position by pressure in the case. The conductor may be in the first position when the pressure in the case corresponds to the normal mode, the conductor may be in the second position when pressure in the case corresponds to the warning and abnormal modes, and the first and second nodes may be connected when the conductor is in the first position and are disconnected when the conductor is in the second position. The first, second, and third inputs may be inputs of an integrated circuit of the protector.

In accordance with one or more other embodiments, a rechargeable battery includes a cell; a node; a first terminal; a second terminal; and a conductor between the node and the first terminal, wherein the conductor is in a first position to connect the node to the first terminal when pressure in a case of the battery corresponds to a normal mode and is to move from the first position to a second position when the pressure in the case corresponds to a warning mode, and wherein the node is disconnected from the first terminal when the conductor is in the second position.

The conductor may have a first flexibility, the case may have a second flexibility, and the first flexibility may be greater than the second flexibility. The pressure in the case corresponding to the warning mode may be less than a pressure in the case corresponding to a predetermined overcharge level. The conductor may remain in the second position when the pressure in the case has reached warning mode as a result of permanent deformation of the conductor. The conductor may have a substantially convex shape in the second position.

### BRIEF DESCRIPTION OF THE DRAWINGS

Features will become apparent to those of skill in the art by describing in detail exemplary embodiments with reference to the attached drawings in which:

FIG. 1 illustrates a protection apparatus for a rechargeable battery;

FIG. 2 illustrates an embodiment of a battery pack; and

FIG. 3 illustrates operations included in an embodiment of a method for protecting a rechargeable battery.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawings, the dimensions of layers and regions may be exaggerated for clarity of illustration. Like reference numerals refer to like elements throughout.

It is to be understood that when any component is referred to as being connected to or coupled to another component, it may be connected directly to or coupled directly to the other component or be connected to or coupled to the other component with a further component intervening therebetween. On the other hand, it is to be understood that when one component is referred to as being connected directly to or coupled directly to another component, it may be connected to or coupled to the other component without a further component intervening therebetween.

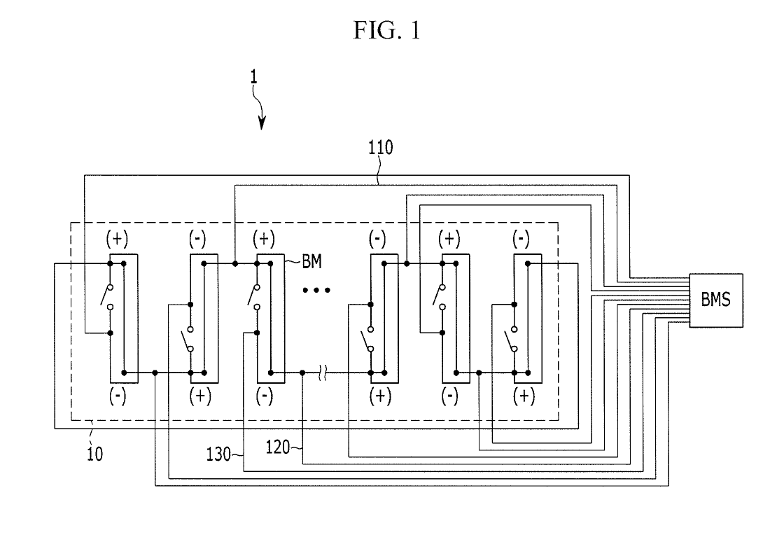

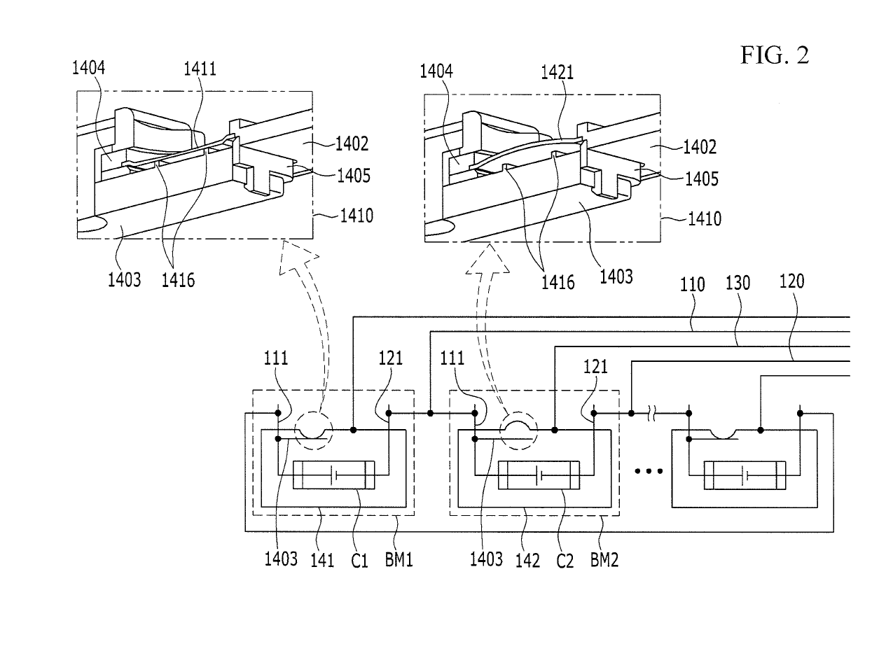

FIG. 1 illustrates an embodiment of a protection apparatus 1 which may be used, for example, for a rechargeable battery or another type of battery. FIG. 2 illustrates an embodiment of a battery pack.

Referring to FIGS. 1 and 2, the protection apparatus 1 includes a battery pack 10 and a battery protection circuit BMS. The protection apparatus 1 may detect a charged state of the battery pack 10 based on a normal mode signal, a warning mode signal, and a protection mode signal generated by the battery protection circuit BMS.

The protection apparatus 1 may determine the charged state of the battery pack 10 to be a normal state based on the normal mode signal. The protection apparatus 1 may detect an increase in internal pressure of the battery pack 10, and recognize and take action to prevent deterioration in over-charging detection performance due to abnormal pressure ventilation of the battery pack 10 or frequent over-charging of the battery protection circuit BMS, in advance based on the warning mode signal. The protection apparatus 1 may perform a protection operation of disconnecting one or more connections between the battery pack 10, a load, and a charger based on the protection mode signal.

The battery pack 10 includes a plurality of battery modules BM, a cathode power line 110, an anode power line 120, and a signal line 130. The cathode power line 110 connects a cathode 111 of the battery module BM to the battery protection circuit BMS. The anode power line 120 connects an anode 121 of the battery module BM to the battery protection circuit BMS. The signal line 130 connects a case 140 of the battery module BM to the protection circuit BMS.

The BMS may be implemented in logic which, for example, may include hardware, software, or both. When implemented at least partially in hardware, the BMS may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the BMS may include, for example, a memory or other storage device for storing code or instructions to be executed. for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

Referring to FIG. 2, respective battery modules BM1 and BM2 may include corresponding unit cells C1 and C2, the case 140, the cathodes 111, and the anodes 121. The cathode 111 of the battery module BM2 is connected to the anode 121 of the neighboring battery module BM1.

The unit cells C1 and C2 may be, for example, a nickel-hydride (Ni—MH) battery, a lithium (Li) ion battery, or another type of battery. As the unit cells C1 and C2 are over-charged, voltages of the unit cells C1 and C2 are excessively increased, which causes the occurrence of gas.

Cases 141 and 142 have a housing shape extending from corresponding unit cells C1 and C2 and ends of a connection module 1410. The cases 141 and 142 may be formed of a conductor such as copper, aluminum, or another conductive material.

The connection module 1410 is on the cases 141 and 142, and may include a conductor 1402, a connection tab 1403, insulators 1404 and 1405, and short plates 1411 and 1421. The conductor 1402 has one end that clamps an end of the short plate 1411 and another end connected to the signal line 130.

The connection tab 1403 is located opposite to the short plates 1411 and 1421. The connection tab 1403 has one end connected to the cathodes and the cathode power line 110 of the unit cells C1 and C2, and another end clamps the insulator 1405. The connection tab 1403 may include a connection point 1416, which may be electrically connected to the short plates 1411 and 1421.

The insulator 1404 clamps one end of the short plates 1411 and 1421.

The insulator 1405 may be between the conductor 1402 and the connection tab 1403, and may electrically insulate the conductor 1402 from the connection tab 1403.

The short plates 1411 and 1421 have one end clamped with the insulator 1404 and another end connected to the cases 141 and 142 through the conductor 1402. The short plates 1411 and 1421 may contact the connection point 1416 of the conductor 1402 or may be spaced apart from the connection point 1416 of the conductor 1402 by a predetermined distance. The short plates 1411 and 1421 may be formed in a contact point forming body, having a shape permanently deformed, for example, by a physical factor such as internal pressure of the case 140, which is increased by gas which forms, for example, when the unit cells C1 and C2 are over-charged.

In one embodiment, the short plates 1411 and 1421 may be deform at a pressure level less than a level that will deform the case. This may be achieved, for example, by making the short plates 1411 and 1421 thinner than a thickness of a wall of the case, and/or by making the short plates of a more malleable metal than the wall of the case.

When the internal pressure of the case 140 is a preset reference value or less. the shape of the short plate 1411 is not deformed and the short plate 1411 may be in contact with the connection point 1416, to connect the cathodes of the unit cells C1 and C2 to the signal line 130. When the internal pressure of the case 140 exceeds the preset reference value, the short plate 1421 is permanently deformed to be convex in an outer direction of the case 140. Once the shape of the short plate 1421 is deformed, the short plate 1421 is not in contact with the connection point 1416. As a result, connections between the cathodes of the unit cells C1 and C2 and the signal line 130 are disconnected.

The signal line 130 has one end connected to the conductor 1402 and another end connected to the battery protection circuit BMS.

The battery protection circuit BMS is connected to the cathode power line 110, the anode power line 120, and the signal line 130. The battery protection circuit BMS measures charging voltages of the corresponding unit cells C1 and C2 through the cathode power line 110 and the anode power line 120, and measures detection voltage of the unit cells C1 and C2 through the signal line 130 and the anode power line 120. The battery protection circuit BMS calculates a voltage ratio (e.g., detection voltage/charging voltage) between the charging voltage and the detection voltage by substituting the measured charging voltage and detection voltage into Equation 1. The battery protection circuit BMS determines charged states of the corresponding unit cells C1 and C2 based on the calculated voltage ratio.

Detection voltage/charging voltage≧0.5: normal state

Detection voltage/charging voltage=0: over-charged state

Detection voltage/charging voltage<0.5: abnormal over-charged state (1)

When the voltage ratio is a first predetermined value (e.g., 0.5) or more, the battery protection circuit BMS determines the charged states of the corresponding unit cells C1 and C2 to be a normal state and generates a normal mode signal. When the voltage ratio is equal to a second predetermined value (e.g., 0), the battery protection circuit BMS determines the charged states of the unit cells C1 and C2 to be an over-charged state and generates a warning mode signal, for monitoring the charged voltages of the corresponding unit cells C1 and C2. When the voltage ratio is less than the first predetermined value, the battery protection circuit BMS determines the charged states of the corresponding unit cells C1 and C2 to be an abnormal over-charged state (e.g., a state where internal pressure of the case is at a failure and/or will produce expulsion of gas through a vent in the case, and/or is at an over-charge pressure greater than the elevated pressure corresponding to the warning mode, etc.) and generates a protection mode, thereby allowing a protection operation to be performed, for example, to disconnect the connection between the battery pack 10, the load, and the charger. In another embodiment, one or both of the first and second predetermined values may be different from 0.5 and 0, respectively.

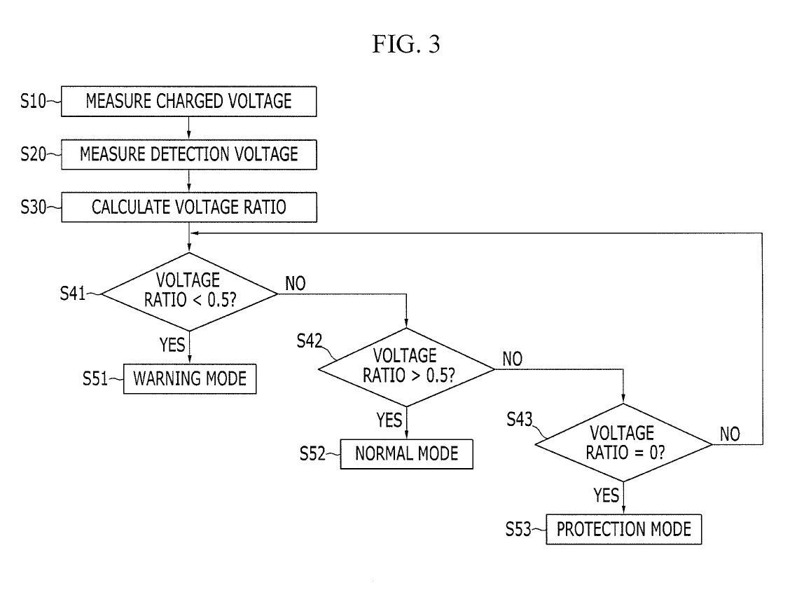

FIG. 3 illustrates operations included in an embodiment of a method for protecting a rechargeable battery. The method may be performed, at least in part, by any of the aforementioned embodiments of the protection apparatus. The method includes measuring charged voltages of corresponding unit cells C1 and C2 through a cathode power line 110 and an anode power line 120 (operation S10). This operation may be performed by a battery protection circuit BMS.

The method further includes measuring detection voltages of the unit cells C1 and C2 through a signal line 130 and the anode power line 120 (operation S20). This operation may also be performed by the battery protection circuit BMS.

The method further includes calculating a voltage ratio (e.g., detection voltage/charged voltage) between the charged voltage/the detection voltage (operation S30). This operation may also be performed by the battery protection circuit BMS.

The method further includes determining whether or not the voltage ratio is less than a first predetermined value (in operation S41), and determining a warning mode when the voltage ratio is less than the first predetermined value (in operation S51). The first predetermined value may be, for example, 0.5. This operation may also be performed by the battery protection circuit BMS.

The method further includes determining whether or not the voltage ratio is the first predetermined value or more (operation S42), and determines a normal mode when the voltage ratio is the first predetermined value or more (operation S52). This operation may also be performed by the battery protection circuit BMS.

The method includes determining whether or not the voltage ratio is equal to a second predetermined value (operation S43), and determines a protection mode the voltage ratio is equal to a second predetermined value (operation S53). The second predetermined value may be, for example, 0. This operation may also be performed by the battery protection circuit BMS. In another embodiment, one or both of the first and second predetermined values may be different from 0.5 and 0, respectively.

The methods, processes, and/or operations described herein may be performed by logic, e.g., hardware, software or both. The software may include code or instructions to be executed by a computer, processor, microprocessor, controller, or other signal processing device. Because the algorithms that form the basis of the methods (or operations of the computer, processor, microprocessor, controller, or other signal processing device) are described in detail, the code or instructions for implementing the operations of the method embodiments may transform the computer, processor, microprocessor, controller, or other signal processing device into a special-purpose processor for performing the methods described herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments described herein.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly. it will be understood by those of skill in the art that various changes in form and details may be made without departing from the spirit and scope of the present invention as set forth in the following claims.

What is claimed is:

1. A protection apparatus for a rechargeable battery, comprising:
a battery module including a unit cell, a conductor case, a cathode, and an anode;
a cathode power line connected to the cathode;
an anode power line connected to the anode;
a signal line connected to the case; and
a battery protector to measure a charged voltage of the unit cell through the cathode power line and the anode power line, to measure a detection voltage of the unit cell through the anode power line and the signal line, and to determine a charged state of the unit cell based on a calculated voltage ratio of the charged voltage and the detection voltage.

2. The protection apparatus as claimed in claim 1, wherein:
the battery module includes a plate extending from the case and connected to the signal line; and
a connection tab connected to the cathode and a connection point in contact with the plate, wherein the plate is to deform when an internal pressure of the battery module exceeds a preset reference value, and wherein contact between the connection point and the plate is broken when the plate deforms.

3. The protection apparatus as claimed in claim 2, wherein the plate is a contact point forming body having a shape to be permanently deformed when the internal pressure of the case exceeds the preset reference value.

4. The protection apparatus as claimed in claim 3, wherein:
when the internal pressure of the case exceeds the preset reference value, the plate is permanently deformed to be convex in an outer direction of the case.

5. The protection apparatus as claimed in claim 1, wherein:
when the voltage ratio is a first predetermined value or more, the battery protector is to determine the charged state of the unit cell to be a normal state, and
when the voltage ratio is less than the first predetermined value, the battery protector is to determine the charged state of the unit cell to be in an abnormal over-charged state.

6. The protection apparatus as claimed in claim 5, wherein:
when the voltage ratio is equal to a second predetermined value, the battery protector is to determine the charged state of the unit cell to be in an over-charged state.

7. A protector, comprising:
a first input coupled to an anode power line;
a second input coupled to a cathode power line;
a third input to receive a pressure signal for a case of the battery; and
logic to generate a mode signal based on signals received through the first, second, and third inputs, wherein the mode signal is indicative of a warning mode indicating that pressure in the battery case at a level between a normal mode and an abnormal mode of the battery, and wherein the logic is to perform a monitoring operation to monitor charged voltages of one or more cells of a rechargeable battery based on the warning mode, the monitoring operation to be performed to determine a change from the warning mode to the abnormal mode.

8. The protector as claimed in claim 7, wherein:
the pressure in the battery case is at a first level in warning mode,
the pressure in the battery case is at a second level in the abnormal mode, and
the second level is greater than the first level.

9. The protector as claimed in claim 8, wherein:
the first level corresponds to a first overcharge state of the battery,
the second level corresponds to a second overcharge state of the battery, and
the second overcharge state is more severe than the first overcharge state.

10. The protector as claimed in claim 7, wherein:
the logic is to generate the mode signal indicative of the warning mode when the pressure signal has a first value and
the logic is to generate the mode signal indicative of the normal mode when the pressure signal has a second value different from the first value.

11. The protector as claimed in claim 10, wherein:
the first value has a zero value, and
the second value is a non-zero value.

12. The protector as claimed in claim 7, wherein:
the logic is to generate the mode signal to be indicative of the warning mode when the pressure signal corresponds to a disconnection between first and second nodes connected to the battery, and
the logic is to generate the mode signal to be indicative of the normal mode when the pressure signal corresponds to a connection between the first and second nodes connected to the battery.

13. The protector as claimed in claim 12, wherein:
the pressure signal corresponding to the warning mode is to be generated when a conductor moves from a first position to a second position by pressure in the case.

14. The protector as claimed in claim 13, wherein:
the conductor is in the first position when the pressure in the case corresponds to the normal mode,
the conductor is in the second position when pressure in the case corresponds to the warning and abnormal modes, and
the first and second nodes are connected when the conductor is in the first position and are disconnected when the conductor is in the second position.

15. The protector as claimed in claim 7, wherein the first, second, and third inputs are inputs of an integrated circuit of the protector.

16. A rechargeable battery, comprising:
a cell;
a node;
a first terminal;
a second terminal; and
a conductor between the node and the first terminal,
wherein the conductor is in a first position to connect the node to the first terminal when pressure in a case of the battery corresponds to a normal mode and is to move from the first position to a second position when the pressure in the case corresponds to a warning mode, and wherein the node is disconnected from the first terminal when the conductor is in the second position.

17. The battery as claimed in claim 16, wherein:
the conductor has a first flexibility,
the case has a second flexibility, and
the first flexibility is greater than the second flexibility.

18. The battery as claimed in claim 16, wherein the pressure in the case corresponding to the warning mode is less than a pressure in the case corresponding to a predetermined overcharge level.

19. The battery as claimed in claim 16, wherein the conductor is to remain in the second position when the pressure in the case has reached warning mode as a result of permanent deformation of the conductor.

20. The battery as claimed in claim 16, wherein the conductor has a substantially convex shape in the second position.
